(19) United States
(12) Patent Application Publication
(10) Pub. No.: US 2025/0089353 A1
(43) Pub. Date: Mar. 13, 2025

(54) ELECTRONIC DEVICE

(71) Applicant: STMicroelectronics International N.V., Geneva (CH)

(72) Inventors: Thomas OHEIX, Grenoble (FR); Matthieu NONGAILLARD, Grenoble (FR)

(73) Assignee: STMicroelectronics International N.V., Geneva (CH)

(21) Appl. No.: 18/820,115

(22) Filed: Aug. 29, 2024

(30) Foreign Application Priority Data
Sep. 7, 2023 (FR) 2309400

(51) Int. Cl. H01L 27/088; H01L 21/8252

(52) U.S. Cl. CPC H10D 84/83; H10D 84/05

(57) ABSTRACT

A device includes trenches. The trenches each include a conductive element configured to electrically couple coupling fingers of transistor gates located on a first side of a first layer, to a second layer extending on the side of a second face of the first layer.

### CROSS-REFERENCE TO RELATED APPLICATION(S)

This application claims the priority benefit of French patent application number FR2309400, filed on Sep. 7, 2023, entitled “Dispositif électronique,” which is hereby incorporated by reference to the maximum extent allowable by law.

### BACKGROUND

### Technical Field

The present disclosure relates generally to electronic devices and more particularly to electronic devices including transistors.

### Description of the Related Art

Many electronic devices include transistors and more particularly common-gate transistors. Common-gate transistors refer to transistors the gates of which are coupled, preferentially connected, together, in such a way that the transistors are controlled by the same control voltage. For example, such transistors could be elementary transistors, i.e., small transistors, all having the same dimensions, coupled together so as to form the equivalent of a transistor of larger dimensions. Thereby, the gates of the elementary transistors are coupled, preferentially connected, together, the drains of the elementary transistors are coupled, preferentially connected, together, and the sources of the elementary transistors are coupled, preferentially connected, together.

It would be beneficial to make sure that the transistors receive the same control voltage and receive said control voltage simultaneously.

### BRIEF SUMMARY

One embodiment provides a device including trenches, the trenches each including a conductive element configured for electrically coupling fingers of transistor gates, located on a first side of a first layer, to a second layer extending on the side of a second face of the first layer.

Another embodiment provides a method for manufacturing a device including the formation of trenches, the trenches each including a conductive element configured for electrically coupling fingers of transistor gates, located on a first side of a first layer, to a second layer extending on a second side of the first layer.

According to an embodiment, the second layer is configured for being biased to the control voltage of the transistors.

According to an embodiment, the transistors are arranged in rows, the transistors of the same row being coupled together by their gates by the same finger, the rows being arranged in columns, the columns being separated, two by two, by a trench, the conductive element of each trench separating two columns, being coupled to one end of each of the fingers of the two columns.

According to an embodiment, each column is located between two trenches, each finger being coupled at one end to the conductive element of one of the two trenches and at another end to the conductive element of the other of the two trenches.

According to an embodiment, the first layer is made of GaN, of AlN or of AlGaN.

According to an embodiment, the device includes a semiconductor substrate on the second side of the first layer, the substrate forming the second layer.

According to an embodiment, each trench includes a cavity extending through the first layer, the bottom of the cavity consisting of the substrate, and the conductive element including a third conductive layer extending over the walls and the bottom of the cavity.

According to an embodiment, the device includes a semiconductive substrate on the second side of the first layer, the face of the substrate furthest from the first layer being covered with a fourth conductive layer, the fourth layer forming the second layer.

According to an embodiment, the third layer is made of metal.

According to an embodiment, each trench includes a cavity extending through the first layer, the bottom of the cavity being located at the face of the substrate closest to the first layer, the conductive element including a third conductive layer extending over the walls and the bottom of the cavity and a portion located in the substrate, in contact with the third layer and in contact with the fourth layer.

According to an embodiment, the third layer is separated from the first layer by a fifth insulating layer.

According to an embodiment, the substrate is made of silicon or made of silicon carbide.

According to an embodiment, each conductive element is coupled to the fingers by tracks and vias of an interconnection network.

According to an embodiment, a device includes a first layer having a first face and a second face and a second layer below the first layer and coupled to the second face of the first layer. The device includes a plurality of fingers on the first side of the first layer, each finger corresponding to a gate of a plurality of transistors and a plurality of trenches in the first layer each including a conductive element electrically coupling the fingers to the second slayer.

According to an embodiment, a method for manufacturing a device includes forming a first layer on a second layer and forming, on a first side of the first layer, a plurality of fingers each corresponding to a collective gate of a plurality of transistors. The method includes forming a plurality of trenches extending from the first side of the first layer to a second side of the first layer and forming, in each trench, a respective conductive element electrically coupling a plurality of the to the second layer.

According to an embodiment, a device includes a semiconductor substrate, a semiconductor layer on the semiconductor substrate, and a first group of transistors. The device includes a first finger extending in a first direction on the semiconductor layer and corresponding to a collective gate of the first group of transistors, a second group of transistors, and a second finger extending in the first direction on the semiconductor layer and corresponding to a collective gate of the second group of transistors. The device includes a trench in the semiconductor layer between the first finger and the second finger and a conductive element in the trench in contact with the semiconductor substrate and electrically coupling the first and second fingers to the semiconductor substrate.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 schematically illustrates a transistor, according to an embodiment;

FIG. 2 schematically illustrates an electronic device, according to an embodiment;

FIG. 3 schematically illustrates an electronic device, according to an embodiment;

FIG. 4 illustrates part of an electronic device, according to an embodiment;

FIG. 5 illustrates another part of the electronic device of FIG. 4, according to an embodiment;

FIG. 6 shows an electronic device, according to an embodiment; and

FIG. 7 illustrates another part of the electronic device of FIG. 6, according to an embodiment.

### DETAILED DESCRIPTION

Like features have been designated by like references in the various figures. In particular, the structural and/or functional features that are common among the various embodiments can have the same references and can dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferentially within 5%.

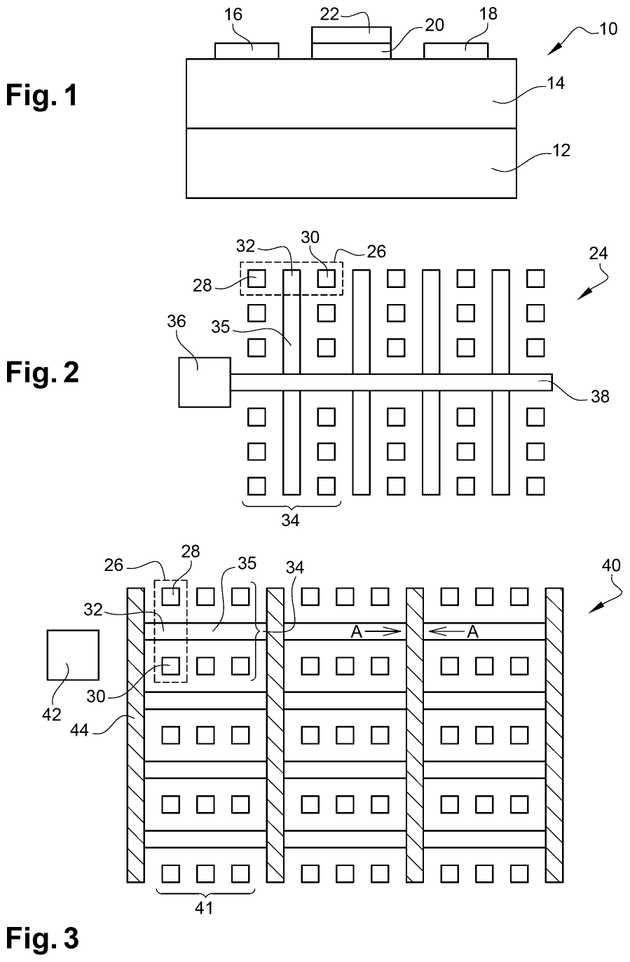

FIG. 1 schematically illustrates an example of a transistor 10 of an electronic device. The electronic device includes for example a chip wherein the transistor is formed.

The transistor 10 is a gallium nitride (GaN) based transistor. The transistor 10 is preferentially a Metal Oxide Semiconductor Field Effect Transistor (MOSFET). The transistor 10 can alternatively be a Schottky gate transistor.

The device includes a substrate 12. The transistor 10 is formed on the substrate 12. The substrate 12 is made of a semiconductor material, for example silicon.

The device includes a layer 14, made of gallium nitride. The layer 14 rests on, and is preferentially in contact with, an upper face of the substrate 12. The layer 14 is for example formed by epitaxy from the substrate 12. The layer 14 can alternatively correspond to a stack of layers including a layer made of GaN, and layers made of AlN and of AlGaN.

The layer 14 for example includes the source and drain regions of the transistor 10. The different regions of the transistor 10 are not shown in FIG. 1.

The device includes a contact element 16, for example made of metal, resting on, and preferentially in contact with, the source region of the transistor 10. The element 16 for example rests on, for example in contact with, the layer 14, more precisely with the source region located in the layer 14. The element 16 preferentially rests on, preferentially in contact with, the upper face of the layer 14.

Similarly, the device includes a contact element 18, for example made of metal, resting on, and preferentially in contact with, the drain region of the transistor 10. The element 18 for example rests on, for example in contact with, the layer 14, more precisely with the drain region located in the layer 14. The element 18 preferentially rests on, preferentially in contact with, the upper face of the layer 14.

The transistor 10 further includes a gate region 20. The region 20 is preferentially made of a semiconductor material, for example of gallium nitride, for a Schottky gate, or of an insulating material, for example made of SiO₂, SiN or Al₂O₃, for an insulated gate. The region 20 preferentially rests on, and is in contact with, the upper face of the layer 14. The gate region is for example located between the elements 16 and 18.

The device further includes a contact element 22, for example made of metal, resting on, and preferentially in contact with, the gate region 20 of the transistor 10.

The lower face of the substrate 12, i.e., the face opposite the upper face, is for example covered by, preferably in contact with, a conductive layer (not shown), for example a metal layer.

The device further includes an interconnection network (not shown). In other words, the device includes insulating layers (not shown) covering the upper face of the device, and thus covering the upper face of the layer 14, the region 20 and the elements 16, 18, 22. Said layers (not shown) include conductive tracks and conductive vias (not shown) for providing connections between the elements of the device or between the device and an external device.

FIG. 2 schematically illustrates an example of an electronic device 24. More precisely, FIG. 2 schematically illustrates a top view of a set of transistors 26. FIG. 2 shows an example of an arrangement of transistors in an electronic device 24, and more precisely illustrates the connections of the transistor gates.

The device 24 includes a plurality of transistors 26. The transistors 26 correspond for example to transistors such as the transistor 10 shown in FIG. 1. However, the transistors 26 could be of another type of gallium nitride transistors, i.e., of another type of transistor the drain and source regions of which are located in a layer of gallium nitride. Thus, the transistor 26 is for example a MOSFET transistor or a p-GaN gate transistor, which is a Schottky gate transistor.

The transistors 26 are for example elementary transistors. The transistors 26 are for example all identical. The transistors 26 have a common-gate. In other words, the gates of all the transistors 26 are coupled, preferentially connected, to each other. The drain of all the transistors are for example coupled, preferably connected, together. The sources of all the transistors are for example coupled, preferably connected, together.

In FIG. 2, each transistor 26 is represented by a source contact element 28, a drain contact element 30 and a gate contact element 32. The elements 28 and 30 correspond for example respectively to the element 16 of FIG. 1 and to the element 18 of FIG. 1. The element 32 corresponds for example to the element 22 of FIG. 1.

The transistors 26 of the device are arranged in rows 34. More precisely, the transistors 26 of a row 34 are arranged in such a way that the pads 28 and 30, respectively, form parallel rows. The different rows 34 are arranged so as to be parallel to each other.

The contact elements 32 of the transistors 26 of a same row 34 consist of portions of the same conductive track 35, in other words of the same finger 35. In other words, the device includes, for each row 34, a conductive track 35, corresponding for example to a conductive track of the interconnection network of the device. The track 35 extends opposite each transistor and is coupled, preferentially connected, to the gate regions of each transistor 26 of the corresponding row 34. Thereby, the transistors of the same row 34 are coupled, preferentially connected, together by the gate.

In the example shown in FIG. 2, the device 24 includes a pad 36 for applying the control voltage, i.e., the voltage supplied to all the gates of the transistors 26. Thereby, the pad 36 receives the control voltage from a voltage source (not shown).

The device 24 further includes a conductive track 38. The track 38 is further coupled, preferentially connected, to the pad 36. For example, the track 38 is a conductive track, or metallization, of the interconnection network of the device. Thereby, the track 38 is for example connected to the pad 36 by conductive vias. The track 38 is thereby biased by the control voltage.

The track 38 extends along a first direction. The fingers extend along another direction, for example a direction perpendicular to the direction of the track 38 in the plane of FIG. 2. The rows 34 of transistors 26 extend along the second direction.

The track 38 is coupled, preferentially connected, to all the tracks 35, so as to supply the control voltage to all the transistors 26.

During an operation of the device, the biasing of the gates of the transistors 26 is provided by the pad 36 and the tracks 35 and 38. However, in devices having a large number of transistors and a large number of fingers, there is a long delay between the moment of application of the control voltage to the pad 36, and thereby on the end of the track 38 close to the pad 36, and the moment at which the other end of the track 38 is biased. Such a delay, caused by the resistivity of the track 38, can be problematic, particularly during peaks of current which can then be concentrated onto a small number of rows 34 instead of being distributed across all the transistors.

FIG. 3 schematically illustrates an embodiment of an electronic device 40. More precisely, FIG. 3 schematically illustrates a top view of a set of transistors 26. FIG. 3 illustrates an example of an arrangement of transistors in an electronic device, and more precisely illustrates the connections of the transistor gates.

Like the device 24 shown in FIG. 2, the device 40 includes a plurality of transistors 26. The transistors 26 correspond for example to transistors such as the transistor 10 shown in FIG. 1. However, the transistors 26 could be of another type of gallium nitride based transistors or of a type of AlGaN or aluminum nitride based transistor (AlN), i.e., another type of transistor the drain and source regions of which are located in a gallium nitride layer.

Like in FIG. 2, the transistors 26 are for example elementary transistors. The transistors 26 are for example all identical. The transistors 26 have a common gate. In other words, the gates of all the transistors 26 are coupled, preferentially connected, to each other.

In FIG. 3, like in FIG. 2, each transistor 26 is represented by a source contact element 28, a drain contact element 30 and a gate contact element 32. The elements 28 and 30 correspond for example to the element 16 of FIG. 1 and to the element 18, respectively, shown in FIG. 1. The element 32 corresponds for example to the element 22 shown in FIG. 1.

The device 40 includes, like the device 24 of FIG. 2, rows 34 of transistors 26. Like in FIG. 2, the transistors 26 of a row 34 are arranged in such a way that the pads 28 and 30, respectively, form parallel rows. The different rows 34 are arranged so as to be parallel to each other.

The contact elements of the transistors 26 of the same row 34 consist of portions of the same conductive track 35, in other words of the same finger 35. In other words, the device includes, for each row 34, a conductive track 35, corresponding for example to a conductive track of the interconnection network of the device. The track 35 extends opposite each transistor and is coupled, preferentially connected, to the gate regions of each transistor 26 of the corresponding row 34. Thereby, the transistors of the same row 34 are coupled, preferentially connected, together by the gate. The drain of all the transistors of a line are for example coupled, preferably connected, together. The sources of all the transistors of a line are for example coupled, preferably connected, together.

To make the representation clear, in the example shown in FIG. 3, each row 34 includes three transistors. The rows could include any number of transistors 26, for example at least ten transistors.

In the example shown in FIG. 3, the rows 34 of transistors are arranged in columns 41. The columns 41 extend, for example in a direction perpendicular to the direction wherein the row extends. Thus, the tracks 35 of the rows of the same column 41 are parallel to one another and are separated from one another by the rows of elements 28 or the rows of elements 30. The columns 41 are parallel to each other. The device includes at least one column, for example at least three columns.

In the example shown in FIG. 3, the device 40 includes a pad 42 for applying the control voltage, i.e., the voltage supplied to all the gates of the transistors 26. Thereby, the pad 42 receives the control voltage from a voltage source (not shown). The pad 42 is preferentially located outside the region wherein the transistors 26 are located. More generally, the device could include a plurality of pads 42, for example located at different places around the transistors 26.

The device includes a conductive or semiconductive layer, not shown in FIG. 3, extending from the lower side of the gallium nitride layer wherein the source and drain regions are located. Thereby, the gate region, i.e., the region 20 in the example shown in FIG. 1, is preferentially separated from said conductive or semiconductive layer by said gallium nitride layer. The track 35 is likewise preferentially separated from said conductive or semiconductive layer by said gallium nitride layer.

The conductive or semiconductive layer (not shown) preferentially extends opposite the entire region of the device wherein the transistors are located. Thereby, all the transistors are located opposite said layer.

The conductive or semiconductive layer (not shown) is biased to the control voltage. The conductive or semiconductive layer is for example coupled, preferentially connected, to the pad 42, more precisely to a lower end of the pad 42. Thereby, the pad 42 preferentially extends from the upper side of the chip wherein the transistors are formed to the lower side of the chip. The upper end of the pad 42 is for example coupled, preferentially connected, to the interconnection network so as to receive the control voltage. The lower end of the pad 42 is coupled, preferentially connected, to the conductive or semiconductive layer, which is thereby biased to the control voltage.

According to another embodiment, the device 40 does not include the pad 42. The conductive or semiconductive layer (not shown) is then coupled to the source of the control voltage without crossing the substrate 12, for example by contact with another device. The conductive or semiconductive layer, not shown, is for example coupled to the source of the control voltage through the layer 54 via the cavity 56.

The device 40 includes trenches 44. Each column 41 is separated from the adjacent column 41 by a trench 44. Preferentially, each column is located between two trenches 44. Each trench 44 preferentially extends along all the sets 34 of transistors 26. In other words, each trench 44 extends from the track 35 of the first set 34 of the column to the track 35 of the last set 34 of the column.

Each trench 44 runs through at least the gallium nitride layer wherein the source and drain regions are located. Each trench 44 reaches the conductive or semiconductive layer.

Each trench 44 includes a conductive element extending as far as the semiconductive or conductive layer and being coupled, directly or by conductive tracks and conductive vias of the interconnection network, to the tracks 35 of the sets 34 of columns 41 located on both sides of the trench 44. Thereby, at least one end of each track 34 is coupled, preferentially connected, by a conductive element of a trench 44, to the conductive or semiconductive layer.

Preferentially, each column is located between two trenches 44. Thereby, the two ends of each track 35 are preferentially coupled, preferentially connected, by conductive elements of the trenches 44 located on both sides of the column 41, to the conductive or semiconductive layer.

The conductive element of each trench 44 is electrically insulated from the gallium nitride layer.

The biasing of the conductive or semiconductive layer is preferentially performed by a plurality of pads 42. Thereby, the whole of said layer is biased to the control voltage. Thereby, the set of transistors 26 is closer to a trench 44, supplying the control voltage than the transistors 26 shown in FIG. 2, are to the pad 36. Although it is possible to have a short delay between the transistors of the same row 34, the delay is much shorter than the delay of FIG. 2. Moreover, the transistors 26 located at the same locations on different rows are at the same distance from the conductive or semiconductive layer.

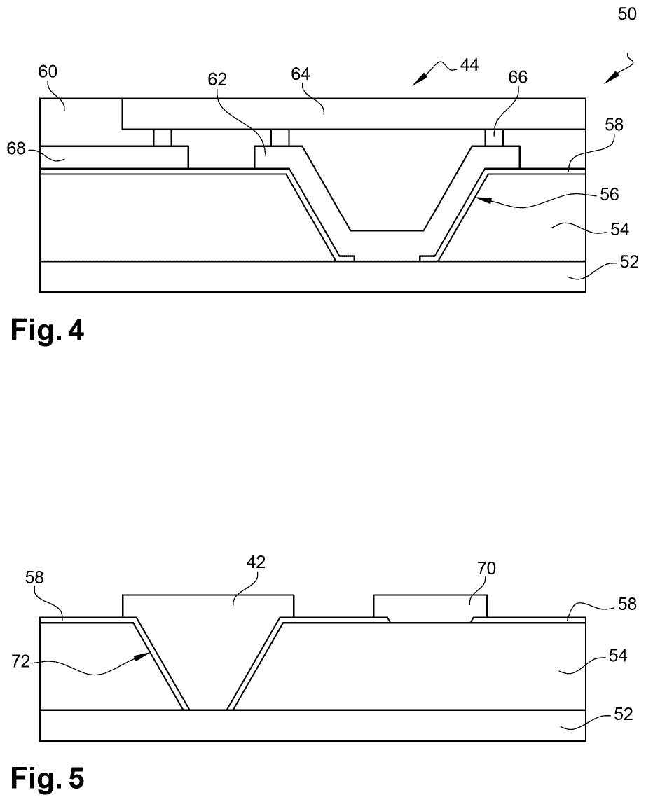

FIG. 4 shows in more detail, a part of the embodiment of an electronic device 50. More precisely, FIG. 4 shows a sectional view of a trench 44 as described in FIG. 3, for example along a plane A-A of FIG. 3, located in a chip of the device 50.

The device 50, and more precisely the chip, includes a substrate 52. The substrate 52 corresponds for example to the substrate 12 shown in FIG. 1. The substrate 12 is preferentially made of a semiconductive material, for example silicon or silicon carbide. The substrate 52 is made of a material different from the layer 54.

The device 50 includes for example a conductive layer (not shown) extending over a lower face of the substrate 52.

The device 50 includes a layer 54 of gallium nitride. The layer 54 has for example a thickness greater than 4 μm. The layer 54 corresponds for example to the layer 14 shown in FIG. 1. Thereby, the source and drain regions of the transistors 26 shown in FIG. 3 are preferentially located in the layer 54. The layer 54 extends over an upper face of the substrate 52. The layer 54 is for example in contact with the layer 52.

The layer 54 includes a cavity 56 extending at least from an upper face of the layer 54 to a lower face of the layer 54. The cavity 56 arrives at the upper face of the substrate 52. Thereby, the bottom of the cavity 56 consists of a portion of the upper face of the substrate 52.

The device 50 includes an insulating layer 58. The layer 58 covers the side walls of the cavity 56. The layer 58 covers for example a peripheral part of the portion of the substrate 52 forming the bottom of the cavity. A central part of the portion of the substrate 52 forming the bottom of the cavity is not covered by the layer 58. The layer 58 covers for example, at least partially, the upper face of the layer 54, for example at least the portion of the upper face of the layer 54 surrounding the cavity 56.

The device 50 includes an interconnection network. In other words, the device 50 includes a stack 60 of insulating layers covering the upper face of the chip. The insulating layers of the stack 60 include conductive tracks and conductive vias for providing connections between the elements of the device 50 or between the device 50 and an external device.

The device 50 includes a conductive element 62, for example made of metal. The conductive element 62 corresponds, for example to a metallization level M0 of an interconnection network, i.e., corresponds, for example to the level of conductive tracks closest to the layer 54.

The element 62 extends at least over the entire height of the trench 56. More precisely, the element 62 arrives at the bottom of the cavity 56 and is in contact with the substrate 52 via the central part of the portion of the substrate 52 forming the bottom of the cavity. The element 62 extends over the walls of the cavity, and more precisely over the layer 58 covering the walls of the cavity. Furthermore, the element 62 extends for example over a portion of the upper face of the layer 54 around the cavity 56, more precisely over the layer 58 covering a portion of the upper face of the layer 54 around the cavity 56, preferentially on both sides of the trench 44. The element 62 is preferentially not in contact with the layer 54. Preferentially, the element 62 is entirely separated from the layer 54 by the insulating layer 58.

In the example shown in FIG. 4, the element 62 does not fill the cavity 56, the element 62 being covered, in the cavity 56, by an insulating material. Alternatively, the element 62 can fill the cavity 56 above the layer 58.

The device 50 further includes a track 64. The track 64 is for example located in a coating level higher than the level of the element 62, for example the level M1. The track 64 preferentially extends over the entire length of the trench 44. Preferentially, the entire trench 44 is thereby covered by the track 64. The element 62 and the track 64 are connected by vias 66. For example, the element 62 and the track 64 are connected by vias located on both sides of the trench, for example, by substantially as many vias 66 on one side of the trench as on the other side of the trench.

In FIG. 4, the device 50 includes for example a conductive track 68. The track 68 corresponds for example to a finger 35 shown in FIG. 3. The track 38 is for example located in the metallization level M0. The track 68 extends for example over, and for example in contact with, the layer 58.

In the example shown in FIG. 4, only one track 68 is shown. In practice, there are as many tracks 68 as there are fingers 35, i.e., as many as there are rows 34. For the trenches 44 located between two rows 34, the track 64 is coupled by vias 66, to the fingers 35 on both sides of the trench.

As a variant, the element 62 is not coupled to the track 68 by the track 64 and the vias 66. The track 68 could be a continuation of the element 62 and thus be in contact with the element 62.

The method for manufacturing the device 50 includes for example:
the formation of the substrate 52;
the formation, if appropriate, of the conductive layer (not shown) on the lower face of the substrate 52;
the formation, for example by epitaxy, of the layer 54;
the etching of the layer 54, for forming the cavity 56;
the formation of the layer 58 over the entire structure;
the etching of the portion of the layer 58 located at the center of the bottom of the cavity 56;
the deposition of the conductive element 62;
an annealing for forming an electrical connection between the element 62 and the substrate (52); and
the formation of the interconnection network.

FIG. 5 illustrates in more detail another part of the device 50 of the embodiment shown in FIG. 4. More precisely, FIG. 5 illustrates a pad 42 shown in FIG. 3 and a pad 70 for applying the drain voltage. The pad 70 is not illustrated in FIG. 3. The pads 42 and 70 are located on the same chip, and in the same device 50 as the structure shown in FIG. 4. Thereby, the structure shown in FIG. 5 includes elements of FIG. 4. The structure shown in FIG. 5 thus includes the substrate 52, the layer 54 and the layer 58. The structure shown in FIG. 5 further includes the interconnection network (not shown). In other words, the structure shown in FIG. 5 includes the stack 60 of insulating layers, not shown in FIG. 5, the stack including conductive tracks and conductive vias.

The device 50 includes a cavity 72 in the layer 54. The cavity 72 extends at least from an upper face of the layer 54 to a lower face of the layer 54. The cavity 72 arrives at the upper face of the substrate 52. Thereby, the bottom of the cavity 72 consists of a portion of the upper face of the substrate 52.

The layer 58 covers the side walls of the cavity 72. The layer 58 covers for example a peripheral part of the portion of the substrate 52 forming the bottom of the cavity. At least a central part of the portion of the substrate 52 forming the bottom of the cavity 72 is not covered by the layer 58. The layer 58 covers for example at least partially, the upper face of the layer 54, for example at least the portion of the upper face of the layer 54 surrounding the cavity 72.

In FIG. 5, the device 50 includes a pad 42, as described in relation to FIG. 3. The pad 42 is preferentially made of a conductive material, for example metal, for example the same material as the element 62 shown in FIG. 4. The pad 42 fills, preferentially entirely, the cavity 72. The pad 42 preferentially covers the portions of the layer 58 located in the cavity 72. The pad 42 is in contact with the substrate 52, more precisely with the portion of the substrate 52 forming the bottom of the cavity 72. The pad preferentially extends from the upper face of the substrate 52 to at least the level of the opening of the cavity 72, preferentially up to a level higher than the opening of the cavity 72. Thereby, the pad 42 includes a part located outside the cavity 72.

The pad 42 is coupled, preferentially connected, to a voltage source supplying the control voltage of the transistors 26 of the rows 34 shown in FIG. 3. The pad 42 is for example coupled, preferentially connected, to said voltage source by the interconnection network (not shown), more precisely by conductive tracks and conductive vias of the interconnection network (not shown).

The device 50 further includes the pad 70. The pad 70 is made of a conductive material, for example metal, for example the same material as the pad 42, for example the same material as the element 62 shown in FIG. 4. The pad 70 crosses through the layer 58 to arrive at the layer 54. The pad 70 is thereby in contact with the layer 54, preferentially with the upper face of the layer 54.

The pad 70 is coupled, preferentially connected, to a voltage source supplying the drain voltage of the transistors 26 of the rows 34 shown in FIG. 3. The pad 70 is for example coupled, preferentially connected, to said voltage source by the interconnection network (not shown), more precisely by conductive tracks and conductive vias of the interconnection network (not shown).

The device 50 includes for example a plurality of pads 42 as described in relation with FIG. 5. The pads 42 are preferentially located around the plurality of transistors 26 shown in FIG. 3. Similarly, the device 50 includes for example a plurality of pads 70 as described in relation with FIG. 5. The pads 70 are preferentially located around the plurality of transistors 26 shown in FIG. 3.

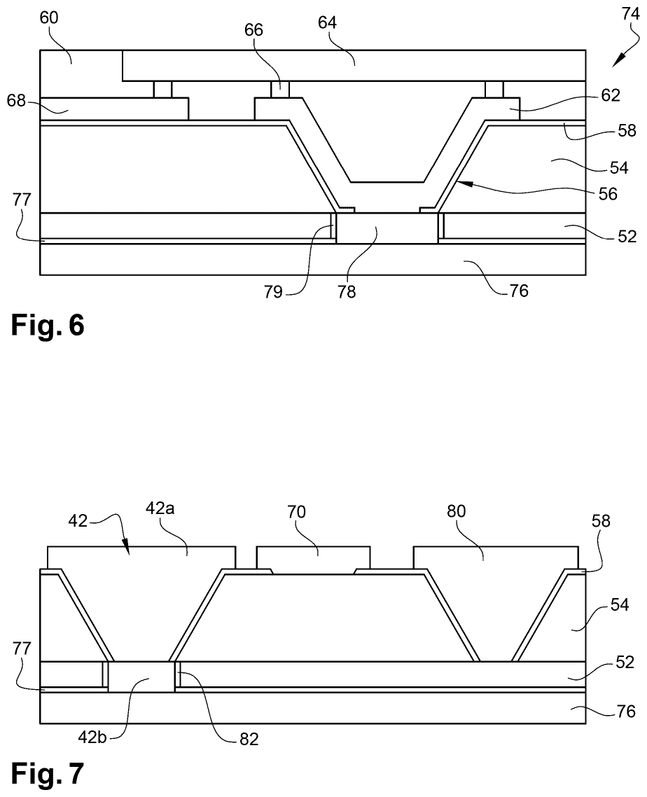

FIG. 6 illustrates in more detail a part of another embodiment of an electronic device 74. More precisely, FIG. 6 shows a sectional view of a trench 44 as described in FIG. 3, for example along a plane A-A of FIG. 3, located in a chip of the device 74.

The device 74 includes elements identical to elements of the device 50. Such elements will not be described again in detail. Thereby, the device 74 includes the substrate 52, the layer 54, the cavity 56, the insulating layer 58, the conductive element 62 and the interconnection network including the stack 60 of insulating layers, the conductive tracks 64, 68 and the conductive vias 66.

The device 74 further includes a conductive layer 76, for example made of metal, covering the lower face of the substrate 52. The layer 76 is for example in contact with the lower face of the substrate 52. The layer 76 extends at least opposite each trench 44.

The device 74 further includes a layer 77. The layer 77 is an insulated layer. The layer 77 separate the layer 76 and the substrate 52. The layer 77 is for example in contact, by its top face, to the substrate 52 and, by its bottom face, to the layer 76. Thus, the layer 76 and the substrate 52 are not in contact.

The device 74 includes, for each trench 44, a conductive element 78, for example made of metal, in the substrate 52. The element 78 crosses the substrate 52 and the layer 77. The element 78 extends from the upper face of the substrate 52 to the lower face of the layer 77. The lower face of the element 78 is in contact with the layer 76. The element 78 is located opposite and in contact with the corresponding trench 44. More precisely, the upper face of the element 78 is at least partially in contact with the element 62. The upper face of the element 78 is for example in contact with the layer 58, for example with the portions of the layer 58 extending over the bottom of the cavity 56. The dimensions of the element 78 are such that the element 62 is not in contact with the substrate 52 and that the element 78 is not in contact with the layer 54. In other words, the dimensions of the element 78 at the plane of the upper face of the substrate 52 are less than or equal to the dimensions of the bottom of the cavity 56. Moreover, the dimensions of the layer 58, and more precisely the dimensions of the portions of the layer 58 covering the bottom of the cavity 56, are such that the central part of the bottom of the cavity 56 not covered by the layer 58, consists entirely of the element 78.

The device further includes a layer 79. The layer 79 surrounds laterally the element 78. The layer 79 separates therefore the element 78 from the substrate 52. The element 78 is thus not in contact with the substrate 52.

In the embodiment shown in FIG. 6, the layer 76 is biased to the control voltage of the transistors 26 shown in FIG. 3. Thereby, the fingers 35 shown in FIG. 3, corresponding for example to the track 68 shown in FIG. 6, are biased by means of the conductive elements 78 and 62. The substrate 52 is for example biased to the source voltage and the layer 54 is for example biased to the drain voltage.

In one embodiment, the device of FIG. 6 does not include the element 78. The cavity 56 is then formed so as to cross through the layer 54 and the substrate 52. The upper face of the layer 76 then forms the bottom of the cavity 56.

An example of a method for manufacturing the device 74 is identical to the method described with reference to FIG. 4, with the exception of the step of forming the substrate 52 which then includes the formation of the element 78.

FIG. 7 illustrates in more detail another part of the embodiment of the device 74 shown in FIG. 6. More precisely, FIG. 7 illustrated a pad 42 for applying the control voltage, a pad 80 for applying the source voltage and a pad 70 for applying the drain voltage.

The pads 42, 70 and 80 are located on the same chip, and in the same device 74 as the structure shown in FIG. 6. Thereby, the structure shown in FIG. 7 includes elements of FIG. 6. The structure shown in FIG. 7 thereby includes the substrate 52, the layer 54, the layer 77, the layer 58 and the layer 76. The structure shown in FIG. 7 further includes the interconnection network (not shown). In other words, the structure shown in FIG. 7 includes the stack 60 of insulating layers, not shown in FIG. 7, the stack including conductive tracks and conductive vias.

The pad 70 is identical to the pad 70 shown in FIG. 5. Thereby, the pad 70 crosses through the layer 58 and is in contact with the layer 54. The pad 70 is coupled, preferentially connected, to a voltage source supplying the drain voltage of the transistors 26 of the rows 34 shown in FIG. 3. The pad 70 is for example coupled, preferentially connected, to said voltage source by the interconnection network (not shown), more precisely by conductive tracks and conductive vias of the interconnection network (not shown).

The pad 80 is identical to the pad 42 shown in FIG. 5. Thereby, the pad 80 is located in a cavity crossing through the layer 54 so as to arrive at the substrate 52. The pad 80 is separated from the layer 54 by the insulating layer 58. The pad 80 is in contact with the substrate 52. The pad 80 differs from the pad 42 shown in FIG. 5 in that the pad 80 receives the source voltage. In other words, the pad 80 is coupled, preferentially connected, to a voltage source supplying the source voltage of the transistors 26 of the rows 34 shown in FIG. 3. The pad 80 is for example coupled, preferentially connected, to said voltage source by the interconnection network (not shown), more precisely by conductive tracks and conductive vias of the interconnection network (not shown).

The pad 42 shown in FIG. 7 includes, like the pad 80 and the pad 42 shown in FIG. 5, a conductive part 42a, for example made of metal, filling a cavity crossing through the layer 54 and the layer 77 so as to arrive at the level of the lower face of the layer 54. The pad 42 includes a conductive part 42b, for example made of metal, located in the substrate 52. The part 42b is for example identical to the element 78 shown in FIG. 6. The part 42b extends from the upper face of the substrate 52 to the lower face of the substrate 52. The upper face of the part 42b is in contact with the part 42a and the lower face of the part 42b is in contact with the layer 76. The upper face of the part 42b is for example in contact with the layer 58. The dimensions of the part 42b are for example such that the part 42b is not in contact with the layer 54, being only in contact with the part 42a and, if appropriate, with the layer 58. The dimensions of the part 42b are for example such that the part 42a is not in contact with the substrate 52.

The pad 42 is coupled, preferentially connected, to a voltage source supplying the control voltage of the transistors 26 of the rows 34 shown in FIG. 3. The pad 42 is for example coupled, preferentially connected, to said voltage source by the interconnection network (not shown), more precisely by conductive tracks and conductive vias of the interconnection network (not shown).

The device further includes a layer 82. The layer 82 surrounds laterally the element 42b. The layer 82 separates therefore the element 42b from the substrate 52. The element 42b is thus not in contact with the substrate 52.

The embodiments described in relation with the FIGS. 3 to 7 are for example destined to be present in circuits of power conversion, for example in vehicle, for example in cars.

An advantage of the embodiments described is that the delay between the application of the control voltage, or a variation of the control voltage, and the reception of the control voltage, or of the control variation, is shorter.

Another advantage of the embodiments described is that a peak of current of the control voltage is less likely to damage the transistors, the peak being shared more rapidly over a larger number of transistors.

Another advantage of the embodiments described is that same do not lead to any modification of the transistors.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

A device (50, 74) includes trenches (44), the trenches (44) each includes a conductive element (62, 78) configured for electrically coupling fingers (35) of transistor gates (26), located on a first side of a first layer (54), to a second layer (52, 76) extending on the side of a second face of the first layer (54).

A method for manufacturing a device (50, 74) includes the formation of trenches (44), the trenches (44) each including a conductive element (62, 78) configured for electrically coupling fingers (35) of transistor gates (26), located on a first side of a first layer (54), to a second layer (52, 76) extending on a second side of the first layer (54).

The second layer (52, 76) is configured for being biased to the control voltage of the transistors (26).

The transistors (26) are arranged in rows (34), the transistors (26) of the same row (34) being coupled together by their gates by the same finger (35), the rows (34) being arranged in columns (41), the columns (41) being separated, two by two, by a trench (44), the conductive element (62, 78) of each trench (44) separating two columns (41), being coupled to one end of each of the fingers (35) of the two columns.

Each column (41) is located between two trenches (44), each finger (35) being coupled at one end to the conductive element (62, 78) of one of the two trenches (44) and at another end to the conductive element (62, 78) of the other of the two trenches (44).

The first layer (54) is made of GaN, of AlN or of AlGaN.

The device (50, 74) includes a semiconductor substrate (52) on the second side of the first layer (54), the substrate (52) forming the second layer.

Each trench (44) includes a cavity (56) extending through the first layer (54), the bottom of the cavity (56) consisting of the substrate (52), and the conductive element (62) comprising a third conductive layer (62) extending over the walls and the bottom of the cavity (56).

The device (50, 74) includes a semiconductive substrate (52) on the second side of the first layer (54), the face of the substrate (52) furthest from the first layer (54) being covered with a fourth conductive layer (76), the fourth layer (76) forming the second layer.

The third layer (76) is made of metal.

Each trench (44) includes a cavity (56) extending through the first layer (54), the bottom of the cavity (56) being located at the face of the substrate (52) closest to the first layer (54), the conductive element (62, 78) includes a third conductive layer (62) extending over the walls and the bottom of the cavity and a portion (78) located in the substrate (52), in contact with the third layer (62) and in contact with the fourth layer (76).

The third layer (62) is separated from the first layer (54) by a fifth insulating layer (58).

The substrate (52) is made of silicon or made of silicon carbide.

Each conductive element (62, 78) is coupled to the fingers (35) by tracks and vias of an interconnection network.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first layer having a first face and a second face;
a second layer below the first layer and coupled to the second face of the first layer;
a plurality of fingers on the first side of the first layer, each finger corresponding to a gate of a plurality of transistors; and
a plurality of trenches in the first layer each including a conductive element electrically coupling the fingers to the second slayer.

2. The device according to claim 1, wherein the second layer is configured to be biased to a control voltage of the transistors.

3. The device according to claim 1, wherein the transistors are arranged in rows, the transistors of the same row having a collective gate corresponding to a same finger, the rows being arranged in columns, the columns being separated, two by two, by a trench, the conductive element of each trench separating two columns and being coupled to one end of each of the fingers of the two columns.

4. The device according to claim 3, wherein each column is located between two trenches, each finger being coupled at one end to the conductive element of one of the two trenches and at another end to the conductive element of the other of the two trenches.

5. The device according to claim 1, wherein the first layer is GaN, of AlN or of AlGaN.

6. The device according to claim 1, wherein second layer is a semiconductor substrate.

7. The device according to claim 6, wherein each trench includes a cavity extending through the first layer, the bottom of the cavity exposing the substrate, and the conductive element including a third conductive layer extending over walls of the cavity and the bottom of the cavity.

8. The device according to claim 1, comprising a fourth conductive layer on a bottom of the second layer and separated from the first layer by the second layer, wherein the second layer is a semiconductor substrate.

9. The device or the method according to claim 8, wherein the third layer is metal.

10. The device according to claim 8, wherein each trench includes a cavity extending through the first layer, a bottom of the cavity being located at the face of the substrate closest to the first layer, the conductive element including a third conductive layer extending over the walls and the bottom of the cavity and a portion located in the substrate, in contact with the third layer and in contact with the fourth layer.

11. The device according to claim 8, wherein the third layer is separated from the first layer by a fifth layer of insulating material.

12. The device according to claim 6, wherein the semiconductor substrate is silicon or made of silicon carbide.

13. The device according to claim 1, wherein each conductive element is coupled to the fingers by tracks and vias of an interconnection network.

14. A method for manufacturing a device, comprising:
forming a first layer on a second layer;
forming, on a first side of the first layer, a plurality of fingers each corresponding to a collective gate of a plurality of transistors;
forming a plurality of trenches extending from the first side of the first layer to a second side of the first layer; and
forming, in each trench, a respective conductive element electrically coupling a plurality of the to the second layer.

15. The method according to claim 14, wherein the second layer is configured to be biased to a control voltage of the transistors.

16. The method of claim 15, comprising forming a metal interconnection structure electrically coupling each finger to at least one of the conductive elements.

17. The method according to claim 14, wherein the transistors are arranged in rows, the transistors of the same row having a collective gate corresponding to a same finger, the rows being arranged in columns, the columns being separated, two by two, by a trench, the conductive element of each trench separating two columns and being coupled to one end of each of the fingers of the two columns.

18. A device, comprising:
a semiconductor substrate;
a semiconductor layer on the semiconductor substrate;
a first group of transistors;
a first finger extending in a first direction on the semiconductor layer and corresponding to a collective gate of the first group of transistors;
a second group of transistors;
a second finger extending in the first direction on the semiconductor layer and corresponding to a collective gate of the second group of transistors;
a trench in the semiconductor layer between the first finger and the second finger; and
a conductive element in the trench in contact with the semiconductor substrate and electrically coupling the first and second fingers to the semiconductor substrate.

19. The device of claim 18, comprising a conductive layer below and in contact with the semiconductor substrate.

20. The device of claim 19, comprising an electrical contact extending through the semiconductor layer, the semiconductor substrate and contacting the conductive layer.
